(19) United States
(12) Patent Application Publication
(10) Pub. No.: US 2024/0088873 A1
(43) Pub. Date: Mar. 14, 2024

(54) SOLID STATE VARIABLE IMPEDANCE DEVICE AND SYSTEM

(71) Applicant: Applied Materials, Inc., Santa Clara, CA (US)

(72) Inventors: DAVID COUMOU, Webster, NY (US); DENNIS BROWN, Pittsford, NY (US)

(21) Appl. No.: 17/941,976

(22) Filed: Sep. 9, 2022

(51) Int. Cl. H03H 11/28; H01J 37/32

(52) U.S. Cl. CPC H03H 11/28; H01J 37/32183; H01J 2237/327

(57) ABSTRACT

Embodiments disclosed herein include an impedance matching network. In an embodiment, the impedance matching network comprises an input, and a first matrix tuning element on a first branch from the input, where the first matrix tuning element comprises a variable capacitance. In an embodiment, the impedance matching network further comprises a transformer on a second branch from the input, where the transformer has at least a first tap, where a second matrix tuning element is on the first tap, and where the second matrix tuning element comprises a variable capacitance. In an embodiment, the impedance matching network further comprises a third matrix tuning element after the transformer on the second branch, where the third matrix tuning element comprises a variable capacitance. In an embodiment, the impedance matching network further comprises an output after the third matrix tuning element on the second branch.

### BACKGROUND

### 1) Field

Embodiments relate to the field of semiconductor manufacturing and, in particular, to solid state variable impedance matching systems for plasma processing systems.

### 2) Description of Related Art

In many semiconductor processing tools, such as plasma processing tools, an RF source is used to couple power into the chamber. The RF power may induce a plasma in order to process a substrate within the chamber. Due to impedance mismatches, some of the forward power is reflected back to the RF source. Accordingly, many processing tools include an impedance matching network in order to match the impedance of the load in the chamber.

Typically, impedance matching networks rely on an electro-mechanical tuning system. Electro-mechanical tuning systems may include vacuum variable capacitors that are driven by a motor, such as a servo motor. Electro-mechanical tuning systems are common in high-power applications due to their superior voltage and current handling attributes. However, electro-mechanical tuning systems are slow. That is, the electro-mechanical tuning can only operate as fast as the motor drive, which is orders of magnitude slower than the ion transition rates across a sheath of the plasma.

Solid state impedance matching networks have been proposed as an alternative to electro-mechanical systems. Solid state solutions have improved speed compared to electro-mechanical systems. However, existing solid state impedance matching networks have some drawbacks. For example, the voltage/current handling capability and resolution in solid state solutions may not be as good as electro-mechanical systems. Additionally solid state impedance matching systems are significantly more expensive than electro-mechanical systems.

### SUMMARY

Embodiments disclosed herein include an impedance matching network. In an embodiment, the impedance matching network comprises an input, and a first matrix tuning element on a first branch from the input, where the first matrix tuning element comprises a variable capacitance. In an embodiment, the impedance matching network further comprises a transformer on a second branch from the input, where the transformer has at least a first tap, where a second matrix tuning element is on the first tap, and where the second matrix tuning element comprises a variable capacitance. In an embodiment, the impedance matching network further comprises a third matrix tuning element after the transformer on the second branch, where the third matrix tuning element comprises a variable capacitance. In an embodiment, the impedance matching network further comprises an output after the third matrix tuning element on the second branch.

Embodiments disclosed herein may also include a matrix tuning element. In an embodiment, the matrix tuning element comprises one or more cells, where each cell comprises an array of diodes coupled to a board, where the array comprises one or more columns of diodes, and where each column comprises four rows of diodes connected in series.

Embodiments disclosed herein may also include a semiconductor processing tool. In an embodiment, the semiconductor processing tool comprises a chamber, an RF source, an electrode coupled to the RF source for inducing RF power into the chamber, and an impedance matching network coupled between the RF source and the electrode. In an embodiment, the impedance matching network comprises a first matrix tuning element on a first branch, where the first matrix tuning element comprises a variable capacitance, a transformer on a second branch, where the transformer has at least a first tap, where a second matrix tuning element is on the first tap, and where the second matrix tuning element comprises a variable capacitance. In an embodiment, the impedance matching network further comprises a third matrix tuning element after the transformer on the second branch, where the third matrix tuning element comprises a variable capacitance.

### BRIEF DESCRIPTION OF THE DRAWINGS

FIG. 1A is a perspective view illustration of a solid state impedance tuning cell, in accordance with an embodiment.

FIG. 1B is a perspective view illustration of a solid state matrix tuning element, in accordance with an embodiment.

FIG. 2A is a circuit diagram of a column of diodes in an impedance tuning cell, in accordance with an embodiment.

FIG. 2B is a circuit diagram of a matrix tuning element, in accordance with an embodiment.

FIG. 3A is a circuit diagram of a solid state impedance tuning network with a plurality of variable capacitors that may each be a cell or a matrix tuning element, in accordance with an embodiment.

FIG. 3B is a circuit diagram of a transformer for a solid state impedance tuning network that includes a plurality of taps, in accordance with an embodiment.

FIG. 4A is a circuit diagram of a solid state impedance tuning network with a plurality of variable capacitors that may each be a cell or matrix tuning element, in accordance with an additional embodiment.

FIG. 4B is a circuit diagram of a solid state impedance tuning network with a plurality of variable capacitors that may each be a cell or matrix tuning element, in accordance with an additional embodiment.

FIG. 5A is a graph of capacitance versus mechanical displacement for an electro-mechanical impedance matching network, in accordance with an embodiment.

FIG. 5B is a graph of capacitance versus DC voltage for a solid state impedance matching network, in accordance with an embodiment.

FIG. 6 is a cross-sectional illustration of a semiconductor processing tool that comprises one or more solid state impedance matching networks, in accordance with an embodiment.

FIG. 7 illustrates a block diagram of an exemplary computer system that may be used in conjunction with a processing tool, in accordance with an embodiment.

### DETAILED DESCRIPTION

Systems described herein include solid state variable impedance matching systems for plasma processing systems. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

As noted above, solid state impedance matching networks have the benefit of being tuned faster than electro-mechanical impedance matching networks. For example, the change in capacitance of solid state impedance matching networks described herein is controlled by changing a DC bias voltage coupled to the circuit. The limitation for the DC bias voltage, which is used to vary the capacitance of a cell arrangement of diodes, is the rise time of the DC power supply. The current draw for the DC power is also a function of the rise time. Reverse bias of diodes, such as those used herein, require low current, and DC power rise-time is expected to be less than 10 μs. Such a short rise time aligns with the RF pulsing requirements of plasma processing tools.

In addition to improved tuning speed, embodiments disclosed herein have improved resolution. The resolution is improved by cells of diodes that are arranged to vary capacitance with a reverse biased DC voltage. The resolution of the DC bias voltages is equivalent to radial electro-mechanical motor drivers. Additionally, voltage and current handling capacity is improved. As used herein, silicon devices are distributed in a cell arrangement to achieve higher current applications. The cells may be arranged with an impedance transformation circuit to lower voltage stress.

In an embodiment, the complexity of solid state impedance matching networks disclosed herein is also minimized. Particularly, adjusting the DC bias circuitry is analogous to motor driven schemes in electro-mechanical systems. Furthermore, the cost of solid state impedance matching networks disclosed herein is reduced compared to existing solid state solutions. Particularly, generic diodes used for the impedance matching cells are suitable for this application. This closes the cost gap between electro-mechanical solutions and solid state solutions.

As will be described in greater detail below, the lowest level building block of variable capacitors used in solid state impedance matching networks is a diode. Particularly, a set of four diodes in electrical series are provided in a column on a board. Multiple columns may be provided in electrical parallel in order to form an impedance tuning cell (or just cell for short). In an embodiment, a plurality of cells may be coupled together in order to form a matrix tuning element. As can be appreciated, the scaling to multiple columns of diodes and/or multiple cells allows for improved resolution and dynamic range of the impedance matching network. In an embodiment, a plurality of variable capacitors may be arranged in a circuit in order to provide the desired tuning of an impedance matching network. In an embodiment, the variable capacitors may each have a variable capacitance. That is, each variable capacitor may have a capacitance range that can be obtained through control of the variable capacitors (e.g., with DC bias voltage). In some instances, each variable capacitor may have different capacitance ranges, or two or more of the variable capacitors may have the same capacitance range.

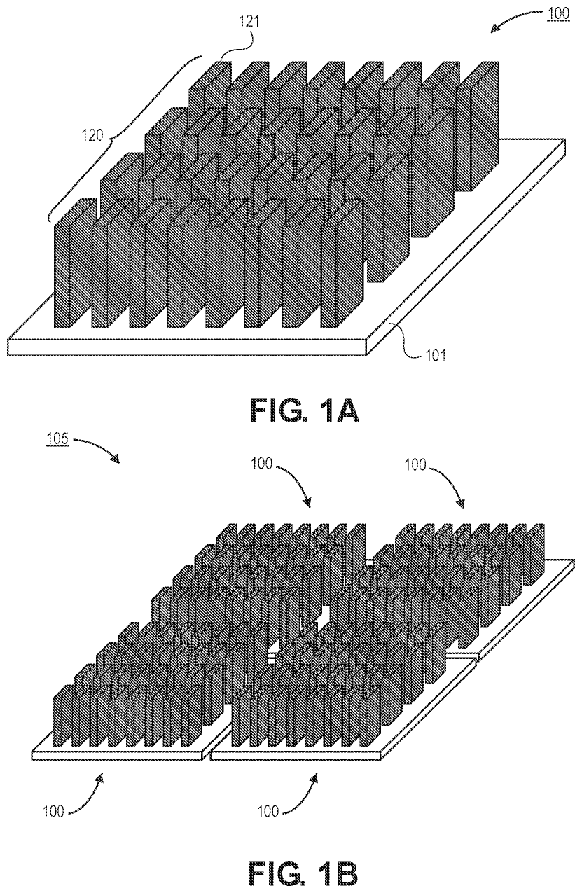

Referring now to FIG. 1A, a perspective view illustration of an impedance matching cell 100 is shown, in accordance with an embodiment. In an embodiment, the impedance matching cell 100 comprises a plurality of diodes 121 that are coupled to a board 101, such as a printed circuit board (PCB). The diodes 121 may be arranged in an array. For example, the array may include a plurality of columns 120 with each column 120 comprising four rows. As will be described in greater detail below, each column 120 of four rows provides the building blocks for the impedance matching network. In the illustrated embodiment, eight columns 120 are shown in FIG. 1. However, it is to be appreciated that one or more columns 120 may be used in some embodiments. Increasing the number of columns 120 increases the resolution achievable by the impedance matching cell 100.

In an embodiment, each of the columns 120 may be electrically coupled to each other in electrical parallel. An input may be provided proximate to a top edge of the board 101, and an output may be provided proximate to a bottom edge of the board 101. The input may be coupled to an RF power source, and the output may be coupled to a load, such as a plasma load of a semiconductor processing tool. Additionally, as will be disclosed in greater detail below, a first capacitor may be provided between the columns 120 and the input, and a second capacitor may be provided between the columns 120 and the output.

In addition to a single impedance matching cell 100, a plurality of impedance matching cells 100 may be coupled together in order to provide a matrix tuning element. That is, a matrix tuning element may be a construction that includes two or more impedance matching cells 100. For example, a matrix tuning element may include up to five impedance matching cells 100. Though, it is to be appreciated that even more impedance matching cells 100 may be included in a matrix tuning element.

Referring now to FIG. 1B, a perspective view illustration of a matrix tuning element 105 is shown, in accordance with an embodiment. The matrix tuning element 105 comprises a plurality of impedance matching cells 100 that are electrically coupled together. As such, impedance tuning can be scaled to larger matrix tuning elements 105 in order to improve resolution and capacitance range of the system. While four impedance matching cells 100 are shown in FIG. 1B, it is to be appreciated that the matrix tuning element 105 may include two or more impedance matching cells 100.

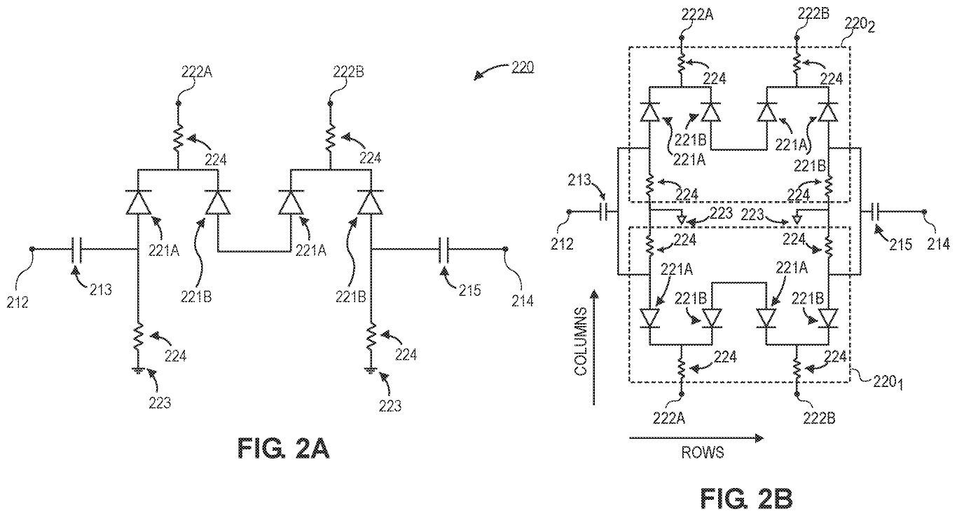

Referring now to FIG. 2A, a circuit diagram of a column 220 of the impedance matching cell 100 is shown, in accordance with an embodiment. In an embodiment, the column 220 may comprise a set of four diodes 221A and 221B connected in series between a first capacitor 213 and a second capacitor 215. The input 212 may be coupled to the first capacitor 213, and the output 214 may be coupled to the second capacitor 215. In an embodiment, the diodes 221 may be arranged as cathodes 221A or anodes 221B. The arrangement between the first capacitor 213 and the second capacitor 215 may include a pattern of cathode diode 221A, anode diode 221B, cathode diode 221A, and anode diode 221B. The diodes 221 may be substantially similar to each other in some embodiments. In other embodiments, the diodes 221 may have different IV characteristics.

In an embodiment, ground connections 223 may be provided between the first capacitor 213 and the first cathode diode 221A, and between the second anode diode 221B and the second capacitor 215. Resistors 224 may be provided before each ground connection 223. In an embodiment, DC bias inputs 222A and 222B may be provided between the first cathode diode 221A and the first anode diode 221B, and between the second cathode diode 221A and the second anode diode 221B. Resistors 224 may be provided before each DC bias input 222A and 222B. Control of the DC bias at the DC bias inputs 222 allows for the value of the capacitance of the column 220 to be modulated in order to provide a desired impedance matching value. In the illustrated embodiment, resistors 224 are provided before each of the DC biases 222A and 222B. However, it is to be appreciated that any high impedance passive device (or devices) may be provided before the DC biases 222A and 222B. Particularly, the high impedance passive devices prevent the flow of RF power to the DC biases 222A and 222B. In an embodiment, the two DC bias inputs 222A and 222B may have the same DC bias applied. In other embodiments, the DC bias of the first DC bias input 222 may be different than the DC bias of the second DC bias input 222. In other embodiments, the bias applied to the DC biases 222A and 222B may be differential biases, pulsed bias, or the like. More particularly, the biases to the DC biases 222A and 222B are not limited to any particular wave form. Additionally, it is to be appreciated that each column 120 in the impedance matching cell 100 can be independently controllable in order to provide a desired value of capacitance to the impedance matching cell 100.

Referring now to FIG. 2B, a circuit diagram of a pair of columns 220₁ and 220₂ is shown, in accordance with an embodiment. As shown, multiple columns 220 can be coupled in parallel between the RF input 212 and the RF output 214. The individual columns 220₁ and 220₂ may be substantially similar to the column 220 described in greater detail above with respect to FIG. 2A. While two columns 220₁ and 220₂ are shown, it is to be appreciated that any number of columns 220 can be provided in parallel between the RF input 212 and the RF output 214.

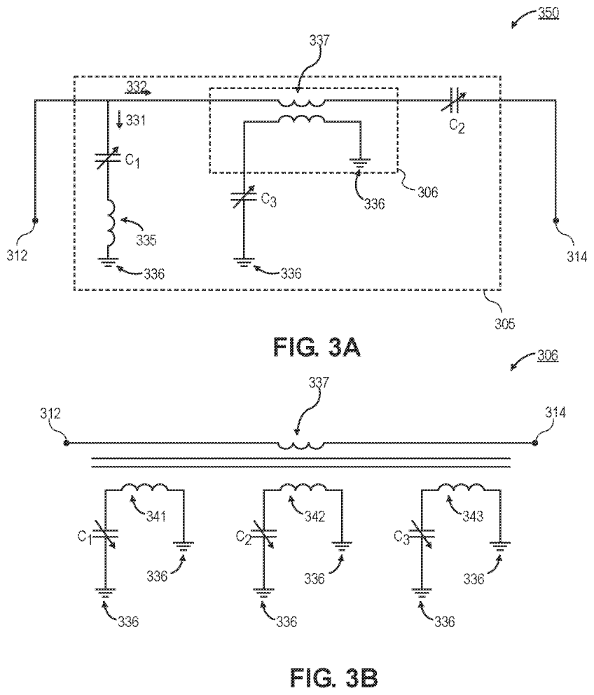

Referring now to FIG. 3A, a circuit diagram of an impedance matching network 350 is shown, in accordance with an embodiment. In an embodiment, the impedance matching network 350 may be a solid state impedance matching network 350. That is, control of the impedance is provided by solid state components such as diodes and the like, as opposed to electro-mechanical solutions that use a motor to drive different capacitances. The circuit between the input 312 and the output 314 may be considered a tuning circuit 305.

In an embodiment, the impedance matching network 350 comprises an input 312 and an output 314. The input 312 receives power from an RF source (not shown), and the output 314 delivers the RF power to a load (not shown), such as a plasma load in a semiconductor processing chamber.

In an embodiment, the input 312 splits to a first branch 331 and a second branch 332. The first branch 331 includes a first variable capacitor C₁, an inductor 335, and a ground 336. The first variable capacitor C₁ may be a matrix tuning element. That is, the first variable capacitor C₁ may comprise a solid state impedance tuning cell, similar to the impedance tuning cell 100 described in greater detail above. As such, the capacitance of the first variable capacitor C₁ is controlled by a pair of DC biases. The first branch 331 may then continue to the inductor 335 which has an output coupled to the ground 336.

In an embodiment, the second branch 332 includes a transformer circuit 306. The transformer circuit 306 may include a transformer 337. In an embodiment, the transformer 337 includes a single tap. Though, as will be described in greater detail below, the transformer 337 may include a plurality of taps. In an embodiment, a first end of the tap includes a third variable capacitor C₃. The third variable capacitor C₃ may be a matrix tuning element. That is, the third variable capacitor C₃ may comprise a solid state impedance tuning cell, similar to the impedance tuning cell 100 described in greater detail above. As such, the capacitance of the third variable capacitor C₃ is controlled by a pair of DC biases. The output of the third variable capacitor C₃ may be coupled to the ground 336. The opposite second end of the tap may be directly coupled to a ground 336.

In an embodiment, a second variable capacitor C₂ may be provided along the second branch 332 between the transformer 337 and the output 314. The second variable capacitor C₂ may be a matrix tuning element. That is, the second variable capacitor C₂ may comprise a solid state impedance tuning cell, similar to the impedance tuning cell 100 described in greater detail above. As such, the capacitance of the second variable capacitor C₂ is controlled by a pair of DC biases.

It is to be appreciated that the plurality of variable capacitors (e.g., C₁, C₂, and C₃) can be independently controlled. As such, various capacitance values may be used to set a desired impedance in the impedance matching network. In some embodiments, all three of the variable capacitors C₁, C₂, and C₃ are formed with solid state impedance tuning cells or matrix tuning elements. In other embodiments, two or one of the variable capacitors C₁, C₂, and C₃ may include solid state impedance tuning cells or matrix tuning elements. The other variable capacitors may include electro-mechanical variable capacitors. That is, embodiments may include both solid state variable capacitors and electro-mechanical variable capacitors. Additionally, it is to be appreciated that the variable capacitors C₁, C₂, and C₃ do not need to have the same range of capacitances. That is, a capacitance range of C₁ may be different than the capacitance ranges of C₂ and/or C₃, the capacitance range of C₂ may be different than the capacitance ranges of C₁ and/or C₃, and the capacitance range of C₃ may be different than the capacitance ranges of C₁ and/or C₂.

Referring now to FIG. 3B, a circuit diagram of a transformer circuit 306 is shown, in accordance with an additional embodiment. In an embodiment, the transformer circuit 306 may be substituted into the impedance matching network 350 described above with respect to FIG. 3A. In an embodiment, the transformer circuit 306 may include a plurality of taps. For example, three taps are provided in FIG. 3B. Though, it is to be appreciated that two or more taps may be included in different embodiments. In an embodiment, inductor 337 may be coupled to inductors 341-343. Each of the inductors 341-343 may be a different tap.

In an embodiment, each of the taps include an inductor 341-343 and a variable capacitor C₁-C₃. Each of the variable capacitors C₁-C₃ may be similar to any of the variable capacitors described in greater detail above. For example, the variable capacitors C₁-C₃ may comprise matrix tuning elements. That is, the variable capacitors C₁-C₂ may comprise solid state impedance tuning cells, similar to the impedance tuning cell 100 described in greater detail above. As such, the capacitance of the variable capacitors C₁-C₃ are each controlled by a pair of DC biases. In an embodiment, each of the taps may further include a pair of grounds 336 on opposite sides of the inductors 341-343. On one side, the output of the inductors 341-343 are directly coupled to a ground 336. The variable capacitors C₁-C₃ are provided between the inductors 341-343 and the grounds 336 on the other side of the inductors 341-343.

In an embodiment, the inductors 341-343 may have non-uniform inductances. In other embodiments, the inductors 341-343 may have the same inductance. Similarly, the variable capacitors C₁-C₃ may be uniform, or the variable capacitors C₁-C₃ may have different capacitance ranges.

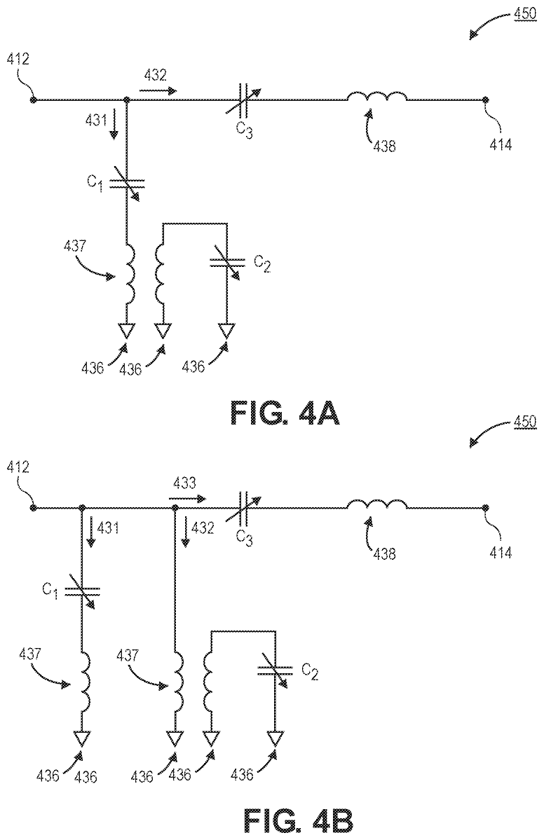

Referring now to FIG. 4A, a circuit diagram of an impedance matching network 450 is shown, in accordance with an additional embodiment. In an embodiment, the impedance matching network 450 may comprise an input 412 and an output 414. The input 412 may be coupled to the RF source, and the output 414 may be coupled to a load, such as a plasma load in a semiconductor processing tool. In an embodiment, the impedance matching network 450 may comprise a first branch 431 and a second branch 432.

The first branch 431 may include a first variable capacitor C₁. A transformer 437 may then be coupled to the output of the first variable capacitor C₁. The transformer 437 may have a single tap that is coupled to a second variable capacitor C₂. The single tap may have two ends that are coupled to grounds 436. In an embodiment, the first branch 431 may terminate at a ground 436 as well. In an embodiment, the second branch 431 may comprise a third variable capacitor C₃. After the third variable capacitor C₃, an inductor 438 may be provided.

In an embodiment, the variable capacitors C₁-C₃ may each be a capacitance tuning cell or a plurality of cells to form a matrix tuning element. The variable capacitors C₁-C₃ may include different capacitance ranges in some embodiments. In other embodiments, two or more of the variable capacitors C₁-C₃ may have the same capacitances ranges.

Referring now to FIG. 4B, a circuit diagram of an impedance matching network 450 is shown, in accordance with an additional embodiment. In an embodiment, the impedance matching network 450 may comprise an input 412 and an output 414. The input 412 may be coupled to the RF source, and the output 414 may be coupled to a load, such as a plasma load in a semiconductor processing tool. In an embodiment, the impedance matching network 450 may comprise a first branch 431, a second branch 432, and a third branch 433.

The first branch 431 may include a first variable capacitor C₁. An inductor 439 may then be coupled to the output of the first variable capacitor C₁. In an embodiment, the first branch 431 may terminate at a ground 436. In an embodiment, the second branch 432 may comprise a transformer 437. The transformer 437 may have a single tap that is coupled to a second variable capacitor C₂. The single tap may have two ends that are coupled to grounds 436. In an embodiment, the second branch 432 may terminate at a ground 436 as well. In an embodiment, the third branch 433 may comprise a third variable capacitor C₃. After the third variable capacitor C₃, an inductor 438 may be provided.

In an embodiment, the variable capacitors C₁-C₃ may each be a capacitance tuning cell or a plurality of cells to form a matrix tuning element. The variable capacitors C₁-C₃ may include different capacitance ranges in some embodiments. In other embodiments, two or more of the variable capacitors C₁-C₃ may have the same capacitances ranges.

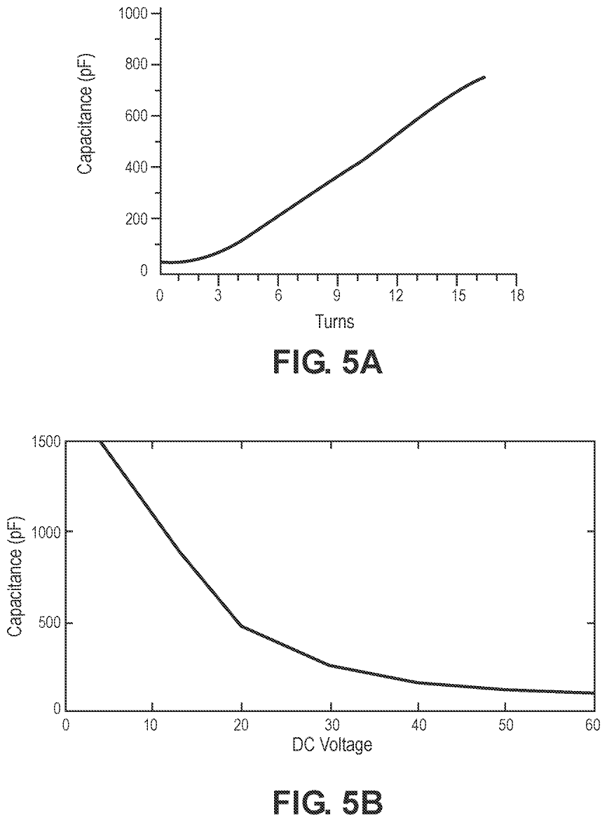

Referring now to FIGS. 5A and 5B, graphs of the capacitance with respect to mechanical displacement (FIG. 5A) and DC bias voltage (FIG. 5B) are shown, in accordance with an embodiment. FIG. 5A is a graph of an electro-mechanical tuning system, and FIG. 5B is a graph of a solid state tuning system, such as those described herein. As shown in FIG. 5A, the resolution of the capacitance is high. That is, there is a substantially continuous output. Such a capacitance relationship enables fine tuning of the impedance. In existing solid state solutions, the output of the capacitance graph is not continuous, and leads to low resolutions.

However, in embodiments disclosed herein, the capacitance graph is continuous. An example of the capacitance versus DC bias voltage is shown in FIG. 5B. As shown, there is a high resolution that enables fine tuning the impedance similar to the electro-mechanical solution plotted in FIG. 5A. Additionally, the curve of FIG. 5B is relatively smooth. As such, performance of the solid state solutions described herein can substantially match those of an electro-mechanical solution. However, as described above, the solid state solutions described herein have response times that are orders of magnitude faster than those of the electro-mechanical solution. Accordingly, embodiments disclosed herein include improved resolution and improved response times, compared to existing solutions.

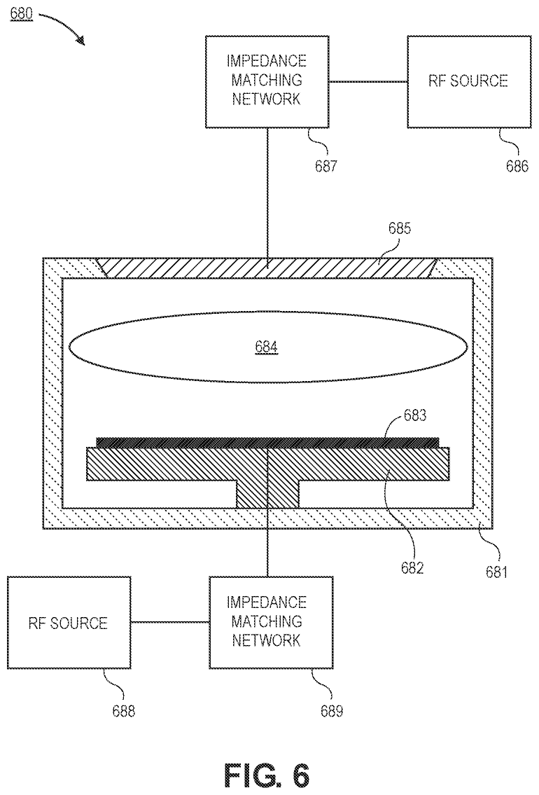

Referring now to FIG. 6, a cross-sectional illustration of a semiconductor processing tool 680 is shown, in accordance with an embodiment. In an embodiment, the semiconductor processing tool 680 may comprise a chamber 681. The chamber 681 may be suitable for supporting low pressure environments, such as pressures close to a vacuum. In an embodiment, a pump and exhaust system may be included (not shown) in order to obtain the low pressure environment. In an embodiment, one or more processing gasses may be flown into the chamber. For example, processing gasses may be flown into the chamber 681 through a lid 685. The lid 685 may be a showerhead type component in order to more evenly distribute gasses into the chamber 681.

In an embodiment, the chamber 681 may comprise a pedestal 682. The pedestal 682 may be suitable for supporting a substrate 683. The pedestal 682 may include heating and/or cooling features in order to control a temperature of the substrate 683 during processing. The substrate 683 may be coupled to the pedestal 682 using any suitable chucking mechanism. For example, an electrostatic chuck, a vacuum chuck, or the like may be used to secure the substrate 683. The substrate 683 may be any substrate that is processed in semiconductor processing tools 680. For example, the substrate 683 may comprise a semiconductor wafer, such as a silicon wafer. Though, other semiconductor materials may also be used. In an embodiment, the wafer has a standard form factor such as 150 mm, 200 mm, 300 mm, 450 mm, or the like. In an embodiment, other substrates (e.g., glass, sapphire, etc.) may also be processed in the chamber 681.

In an embodiment, an RF source 686 may be coupled to the chamber 681. Particularly, the RF source 686 may be coupled to the lid 685 or other electrode in the chamber 681. The RF source 686 produces RF power that can be coupled to processing gasses within the chamber 681 in order to form a plasma 684 for processing the substrate 683. In order to maximize forward power into the chamber 681 (with minimal reflected power), an impedance matching network 687 may be provided between the RF source 686 and the lid 685.

In an embodiment, the impedance matching network 687 may be substantially similar to any of the impedance matching networks described in greater detail herein. Particularly, the impedance matching network 687 may be a solid state impedance matching network 687. For example, the impedance matching network 687 may comprise variable capacitors that are formed with an array of diodes. The array of diodes may be arranged in rows of four with any number of parallel columns on a board to form a cell. Multiple cells may be coupled together to form matrix tuning elements. The capacitance of the variable capacitors (i.e., the variable capacitance) can be controlled with DC bias voltage. As noted above, the rise time of the DC bias voltage may be approximately 10 μs or less. As such, agile and precise control of the variable capacitances is enabled in order to control the impedance of the impedance matching network 687. In an embodiment, the variable capacitors may each have a variable capacitance. That is, each variable capacitor may have a capacitance range that can be obtained through control of the variable capacitors (e.g., with DC bias voltage). In some instances, each variable capacitor may have different capacitance ranges, or two or more of the variable capacitors may have the same capacitance range.

In an embodiment, the semiconductor processing tool 680 may also comprise a second RF source 688. The second RF source 688 may be coupled to the pedestal 682 and/or the substrate 683. The second RF source 688 may be used in conjunction with the RF source 686. In other embodiments, the second RF source 688 may be used instead of the RF source 686. The second RF source 686 may be coupled to the chamber through a second impedance matching network 689.

In an embodiment, the second impedance matching network 689 may be substantially similar to any of the impedance matching networks described in greater detail herein. Particularly, the second impedance matching network 689 may be a solid state impedance matching network 689. For example, the second impedance matching network 689 may comprise variable capacitors that are formed with an array of diodes. The array of diodes may be arranged in rows of four with any number of parallel columns on a board to form a cell. Multiple cells may be coupled together to form matrix tuning elements. The capacitance of the variable capacitors can be controlled with DC bias voltage. As noted above, the rise time of the DC bias voltage may be approximately 10 μs or less. As such, agile and precise control of the variable capacitances is enabled in order to control the impedance of the second impedance matching network 689.

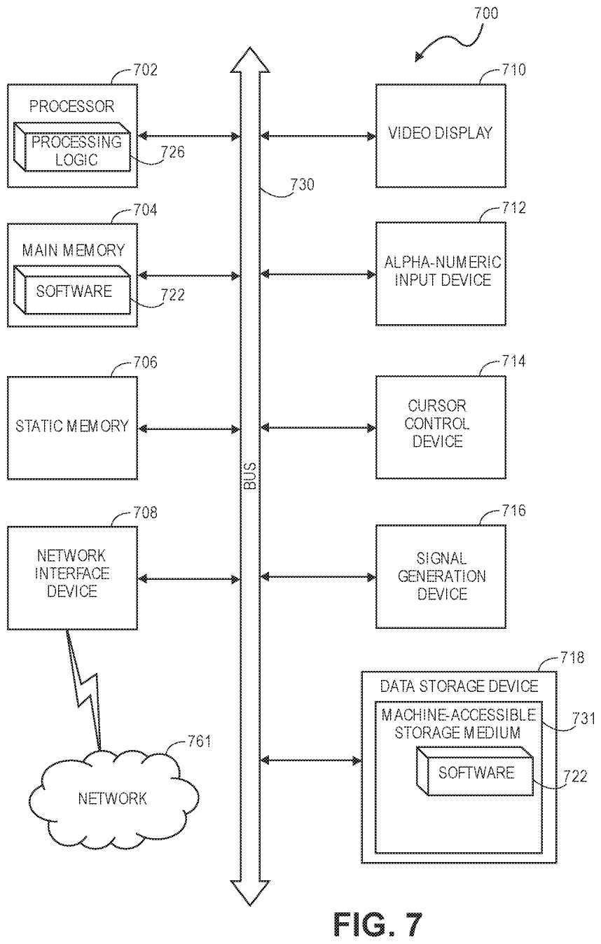

Referring now to FIG. 7, a block diagram of an exemplary computer system 700 of a processing tool is illustrated in accordance with an embodiment. In an embodiment, computer system 700 is coupled to and controls processing in the processing tool. Computer system 700 may be connected (e.g., networked) to other machines in a Local Area Network (LAN), an intranet, an extranet, or the Internet. Computer system 700 may operate in the capacity of a server or a client machine in a client-server network environment, or as a peer machine in a peer-to-peer (or distributed) network environment. Computer system 700 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 700, the term “machine” shall also be taken to include any collection of machines (e.g., computers) that individually or jointly execute a set (or multiple sets) of instructions to perform any one or more of the methodologies described herein.

Computer system 700 may include a computer program product, or software 722, having a non-transitory machine-readable medium having stored thereon instructions, which may be used to program computer system 700 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 700 includes a system processor 702, a main memory 704 (e.g., read-only memory (ROM), flash memory, dynamic random access memory (DRAM) such as synchronous DRAM (SDRAM) or Rambus DRAM (RDRAM), etc.), a static memory 706 (e.g., flash memory, static random access memory (SRAM), etc.), and a secondary memory 718 (e.g., a data storage device), which communicate with each other via a bus 730.

System processor 702 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 702 may also be one or more special-purpose processing devices such as an application specific integrated circuit (ASIC), a field programmable gate array (FPGA), a digital signal system processor (DSP), network system processor, or the like. System processor 702 is configured to execute the processing logic 726 for performing the operations described herein.

The computer system 700 may further include a system network interface device 708 for communicating with other devices or machines. The computer system 700 may also include a video display unit 710 (e.g., a liquid crystal display (LCD), a light emitting diode display (LED), or a cathode ray tube (CRT)), an alphanumeric input device 712 (e.g., a keyboard), a cursor control device 714 (e.g., a mouse), and a signal generation device 716 (e.g., a speaker).

The secondary memory 718 may include a machine-accessible storage medium 732 (or more specifically a computer-readable storage medium) on which is stored one or more sets of instructions (e.g., software 722) embodying any one or more of the methodologies or functions described herein. The software 722 may also reside, completely or at least partially, within the main memory 704 and/or within the system processor 702 during execution thereof by the computer system 700, the main memory 704 and the system processor 702 also constituting machine-readable storage media. The software 722 may further be transmitted or received over a network 720 via the system network interface device 708. In an embodiment, the network interface device 708 may operate using RF coupling, optical coupling, acoustic coupling, or inductive coupling.

While the machine-accessible storage medium 732 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. An impedance matching network, comprising:
an input;
a first matrix tuning element on a first branch from the input, wherein the first matrix tuning element comprises a first variable capacitance;
a transformer on a second branch from the input, wherein the transformer has at least a first tap, wherein a second matrix tuning element is on the first tap, and wherein the second matrix tuning element comprises a second variable capacitance;
a third matrix tuning element after the transformer on the second branch, wherein the third matrix tuning element comprises a third variable capacitance; and
an output after the third matrix tuning element on the second branch.

2. The impedance matching network of claim 1, wherein the first matrix tuning element, the second matrix tuning element, and the third matrix tuning element are identical to each other.

3. The impedance matching network of claim 1, wherein two or more of the first matrix tuning element, the second matrix tuning element, and the third matrix tuning element are different from each other.

4. The impedance matching network of claim 1, wherein the first matrix tuning element, the second matrix tuning element, and the third matrix tuning element each comprise at least four diodes connected to each other in series.

5. The impedance matching network of claim 4, wherein the four diodes include a first cathode diode, a first anode diode, a second cathode diode, and a second anode diode.

6. The impedance matching network of claim 5, wherein a ground connection is provided before the first cathode diode, and after the second anode diode.

7. The impedance matching network of claim 5, wherein a first DC bias is connected between the first cathode diode and the first anode diode, and wherein a second DC bias is connected between the second cathode diode and the second anode diode.

8. The impedance matching network of claim 7, wherein the first DC bias and the second DC bias are differential biases or pulsed biases

9. The impedance matching network of claim 1, wherein one or more of the first matrix tuning element, the second matrix tuning element, and the third matrix tuning element comprises:
an impedance tuning cell with two or more columns of diodes, wherein each column comprises four rows of the diodes connected in series.

10. The impedance matching network of claim 8, wherein two or more columns of diodes are electrically in parallel.

11. The impedance matching network of claim 8, wherein the matrix tuning elements each comprise a plurality of impedance tuning cells.

12. The impedance matching network of claim 1, wherein the transformer comprises three or more taps, and wherein each tap includes a matrix tuning element.

13. The impedance matching network of claim 1, wherein the output is coupled to a plasma processing tool, and wherein the input is coupled to an RF power source.

14. The impedance matching network of claim 1, wherein at least one of the first matrix tuning element, the second matrix tuning element, and the third matrix tuning element are solid state devices, and wherein at least one of the first matrix tuning element, the second matrix tuning element, and the third matrix tuning element are electro-mechanical devices.

15. A matrix tuning element, comprising:
one or more cells, wherein each cell comprises:
an array of diodes coupled to a board, wherein the array comprises one or more columns of diodes, and wherein each column comprises four rows of diodes connected in series.

16. The matrix tuning element of claim 15, wherein the four rows of diodes comprises:
a first cathode diode;
a first anode diode;
a second cathode diode; and
a second anode diode.

17. The matrix tuning element of claim 16, wherein a first DC bias connection is provided between the first cathode diode and the first anode diode, and wherein a second DC bias connection is provided between the second cathode diode and the second anode diode.

18. A semiconductor processing tool, comprising:
a chamber;
an RF source;
an electrode coupled to the RF source for inducing RF power into the chamber; and
an impedance matching network coupled between the RF source and the electrode, wherein the impedance matching network comprises:
a first matrix tuning element on a first branch, wherein the first matrix tuning element comprises a first variable capacitance;
a transformer on a second branch, wherein the transformer has at least a first tap, wherein a second matrix tuning element is on the first tap, and wherein the second matrix tuning element comprises a second variable capacitance; and
a third matrix tuning element after the transformer on the second branch, wherein the third matrix tuning element comprises a third variable capacitance.

19. The semiconductor processing tool of claim 18, wherein the first matrix tuning element, the second matrix tuning element, and the third matrix tuning element each comprise a plurality of cells, wherein each cell comprises a plurality of columns of diodes, and wherein each column comprises four rows of diodes coupled together in series.

20. The semiconductor processing tool of claim 18, wherein the first matrix tuning element, the second matrix tuning element, and the third matrix tuning element have variable capacitances that are controlled by a DC bias.
